(19) United States
(12) Patent Application Publication
(10) Pub. No.: US 2014/0290579 A1
(43) Pub. Date: Oct. 2, 2014

(54) SINGLE POINT LINEAR EVAPORATION SOURCE SYSTEM

(71) Applicant: EverDisplay Optronics (Shanghai) Limited, Shanghai (CN)

(72) Inventors: Chinchih Lin, Shanghai (CN); Haoyu Chou, Shanghai (CN); Chunyun Huang, Shanghai (CN)

(73) Assignee: EverDisplay Optronics (Shanghai) Limited, Shanghai (CN)

(21) Appl. No.: 13/954,259

(22) Filed: Jul. 30, 2013

(30) Foreign Application Priority Data
Apr. 1, 2013 (CN) 201310111467.9

(51) Int. Cl. C23C 16/455

(52) U.S. Cl. CPC C23C 16/45578
USPC 118/726

(57) ABSTRACT

The disclosure discloses a single point linear evaporation source system comprising a body, an evaporator and two guiding plates. The body comprises an elongated chamber, and the surface of the body towards the substrate is provided with a plurality of nozzles communicating with the chamber for ejecting evaporating vapor towards the substrate. The evaporator comprises an opening portion communicating with the chamber. Two guiding plates are disposed inclinedly at two ends of the chamber, and the periphery of the guiding plates are in sealing connection with the body, and the distance between two ends of the two guiding plates adjacent to the substrate is larger than the distance between two ends of the two guiding plates adjacent to the evaporator. The disclosure improves the balance performance of the vapor pressure inside the chamber, and improves the uniformity of the film deposited on the substrate.

### CROSS-REFERENCE TO RELATED APPLICATIONS

This application claims benefits of Chinese Patent Application No. 201310111467.9, filed on Apr. 1, 2013 in the State Intellectual Property Office of China, the disclosure of which is incorporated herein by reference in its entirety.

### BACKGROUND

The present disclosure relates to an evaporation source system and, more particularly, to a single point linear evaporation source system.

Currently, organic light emitting diode (OLED) components are mainly manufactured by evaporation. Either manufacturers or users of the evaporation source aim to improve the performance of the evaporation source, such as the improvement of the material utilization, the reduction of the material cost, and the improvement of the performance of the OLED components such as the thickness and uniformity of deposited films.

The conventional evaporation sources used in thermal evaporation process mainly comprise a point evaporation source system, a cluster-type linear evaporation source system, a single point type linear evaporation source system and a planar evaporation source system. The point evaporation source system comprises a crucible for containing evaporation material to be evaporated, above which a substrate is disposed. In depositing films, the point evaporation source system has the disadvantages of low material utilization, which is usually less than 10%, and unpreferable film uniformity, which is less than 10%. The film uniformity is calculated by the formula of: (maximum film thickness−minimum film thickness)/(maximum film thickness+minimum film thickness). The cluster-type linear evaporation source system comprises at least two elongated slot-shaped crucibles arranged in parallel, and different materials are laid on the bottom of the elongate slot-shaped crucible. Although the uniformity of the film deposited by the cluster-type liner evaporating source system is preferable (less than 5%), the material utilization is low (only 10%-20%). The planar evaporation source system comprises a body having an area larger than or equal to the target area to be deposited. Material utilization of the planar evaporation source system in depositing film is preferable (larger than 40%), but the film uniformity is unstable (less than 10%).

As shown in FIG. 1, the conventional single point linear evaporation source comprises an elongated body 10. The body 10 comprises a chamber therein, and a plurality of nozzles 12 are provided at the top of the body 10. The body 10 communicates with the crucible 20 in the center. When the film is deposited on a substrate 100 by evaporation, the crucible 20 is heated by a heating device (not shown), the evaporation material inside the crucible 20 is heated and vaporized to flow into the chamber of the body 10 and is ejected to the substrate 100 via the nozzles 12, thereby depositing a film on the lower surface of the substrate 100.

In the conventional single point linear evaporation source system, since the body 10 is elongated and the crucible 20 is connected to the bottom of the body 10 in the center, the vapor flowing into the chamber is more concentrated at the center of the body 10 adjacent to the crucible 20 and less concentrated at two ends of the body far away from the crucible 20. That is, the saturation vapor pressure in the chamber is unbalanced. As a result, the film thickness is not uniform, especially at two ends of the substrate 100. When a film with large size is manufactured, the uniformity of the film manufactured by the conventional single point linear evaporation source system is worse.

The above information disclosed in this Background section is only for enhancement of understanding of the background of the disclosure and therefore it may contain information that does not form the prior art that is already known in this country to a person of ordinary skill in the art.

### SUMMARY

The disclosure provides a single point linear evaporation source system with which a film with better uniformity can be deposited.

Additional aspects and advantages will be set forth in part in the description which follows and, in part, will be apparent from the description, or may be learned by practice of the disclosure.

According to an embodiment of the disclosure, a single point linear evaporation source system for depositing film on a substrate comprises:

a body with elongated shape comprising an elongated chamber, the surface of the body towards the substrate being provided with a plurality of nozzles communicating with the chamber, the nozzles being used for ejecting evaporating vapor towards the substrate;

an evaporator with an opening portion communicating with the chamber, the evaporator being used for evaporating evaporation material disposed therein;

two guiding plates disposed inclinedly at two ends of the chamber, the periphery of the guiding plates being in sealing connection with the body, and the distance between two ends of the two guiding plates adjacent to the substrate being larger than the distance between two ends of the two guiding plates adjacent to the evaporator.

According to an embodiment of the disclosure, wherein the guiding plates are disposed at the body with an angle between the guiding plates and the body adjustable.

According to an embodiment of the disclosure, wherein the single point linear evaporation source system further comprises an electric engine or a motor, each of the guiding plates comprises a first plate and a second plate, a top portion of the first plate is rotatably connected to the body, the upper portion of the second plate is slidably connected to the lower portion of the first plate, an output shaft of the electric engine or the motor passes through a through hole of the body and is connected to the first plate.

According to an embodiment of the disclosure, wherein one of the lower portion of the first plate and the upper portion of the second plate is provided with a hollow space, and the other one of the lower portion of the first plate and the upper portion of the second plate is capable of inserting in the hollow space.

According to an embodiment of the disclosure, wherein the upper portion of the second plate overlaps the lower portion of the first plate, one of the second plate and the first plate is provided with at least a recess, the other one of the second plate and the first plate is provided with at least a protruding bar whose shape matches the recess.

According to an embodiment of the disclosure, wherein the recess is dovetail-shaped or ellipse-shaped.

According to an embodiment of the disclosure, wherein the single point linear evaporation source system further comprises a connection pipe whose one end communicates with the opening portion of the evaporator, and the other end communicates with the chamber. An inner diameter of the connection pipe is smaller than that of the opening portion of the evaporator.

According to an embodiment of the disclosure, wherein the single point linear evaporation source system further comprises:

an exhaust pipe whose one end communicates with the connection pipe;

a vapor collecting box communicating with the other end of the exhaust pipe;

a valve assembled inside the connection pipe;

when the single point linear evaporation source system is operated, the valve is in the state of connecting the evaporator and the chamber and cutting off the evaporator and the exhaust pipe, when the single point linear evaporation source system is stopped, the valve is in the state of cutting off the evaporator and the chamber and connecting the chamber and the exhaust pipe.

According to an embodiment of the disclosure, wherein the single point linear evaporation source system further comprises:

a three-way valve comprising three ways, in which a first way communicates with the evaporator, a second way communicates with the chamber of the body;

an exhaust pipe whose one end communicates with a third way of the three-way valve;

a vapor collecting box connected to the other end of the exhaust pipe;

when the single point linear evaporation source system is operated, the first way, the second way are opened, and the third way is closed, when the single point linear evaporation source system is stopped, the first way is closed, and the second way and the third way are opened.

According to an embodiment of the disclosure, wherein the nozzles adjacent to the two ends of the body point to the end of the substrate.

According to an embodiment of the disclosure, wherein the diameters of the nozzles in the center of the body are smaller than those at two ends of the body.

According to an embodiment of the disclosure, wherein the length of the body is smaller than the length of the substrate.

According to an embodiment of the disclosure, wherein the length of the body is ½˜⅘ of the length of the substrate.

According to an embodiment of the disclosure, wherein the evaporator is crucible.

According to an embodiment of the disclosure, wherein the two guiding plates are symmetrical to each other.

According to an embodiment of the disclosure, wherein the nozzles adjacent to the two ends of the body are disposed inclinedly.

According to an embodiment of the disclosure, wherein the nozzles are disposed at a nozzle plate, and the nozzle plate is disposed on the body.

According to an embodiment of the disclosure, wherein the nozzle plate and the body are integrally formed.

According to an embodiment of the disclosure, wherein the guiding plates and the body are integrally formed.

According to an embodiment of the disclosure, wherein the body is made of galvanized iron or titanium.

According to an embodiment of the disclosure, wherein the guiding plates are made of galvanized iron or titanium.

According to an embodiment of the disclosure, wherein the guiding plates are curved.

### BRIEF DESCRIPTION OF THE DRAWINGS

The present disclosure will become more fully understood from the detailed description given hereinafter and the accompanying drawings which are given by way of illustration only, and thus are not limitative of the present disclosure and wherein:

FIG. 1 is a perspective view diagram showing the structure of a conventional single point linear evaporation source system.

FIG. 2 is a perspective view diagram showing the structure of a single point linear evaporation source system in the first embodiment of the disclosure.

FIG. 3 is a perspective view diagram showing the structure of a single point linear evaporation source system in the second embodiment of the disclosure.

FIG. 4 is a perspective view diagram showing the structure of a single point linear evaporation source system in the third embodiment of the disclosure.

FIG. 5 is a perspective view diagram showing the structure of a single point linear evaporation source system in the fourth embodiment of the disclosure.

FIG. 6 is a perspective view diagram showing the effect of the single point linear evaporation source system in the third and fourth embodiments of the disclosure.

FIG. 7 is a perspective view diagram showing the structure of a single point linear evaporation source system in the fifth embodiment of the disclosure.

FIG. 8A is a perspective view diagram showing the structure of a single point linear evaporation source system in the sixth embodiment of the disclosure.

FIG. 8B is a sectional view diagram taken along line A-A in FIG. 8A.

FIG. 9A is a perspective view diagram showing the structure of a single point linear evaporation source system in the seventh embodiment of the disclosure.

FIG. 9B is a sectional view diagram taken along line B-B in FIG. 9A.

### MAIN REFERENCE NUMERALS AND ELEMENTS

100: substrate
10: body
12: nozzle
20: crucible
30: connection pipe
40: exhaust pipe
50: vapor collecting box
60: three-way valve
70: guiding plate
71: first plate
711: dovetail protruding bar
712: ellipse protruding bar
72: second plate
80: electric engine
81: output shaft

### DETAILED DESCRIPTION

Exemplary embodiments of the disclosure will now be described more fully with reference to the accompanying drawings, in which exemplary embodiments are shown. Exemplary embodiments of the disclosure may, however, be embodied in many different forms and should not be construed as being limited to the embodiments set forth herein; rather, these embodiments are provided so that this disclosure will be thorough and complete, and will fully convey the concept of exemplary embodiments to those skilled in the art. In the drawings, the thicknesses of layers and regions are exaggerated for clarity. Like reference numerals in the drawings denote like elements, and thus their description will be omitted.

The described features, structures, or/and characteristics of the disclosure may be combined in any suitable manner in one or more embodiments. In the following description, numerous specific details are disclosed to provide a thorough understanding of embodiments of the disclosure. One skilled in the relevant art will recognize, however, that the disclosure may be practiced without one or more of the specific details, or with other methods, components, materials, and so forth. In other instances, well-known structures, materials, or operations are not shown or described in detail to avoid obscuring aspects of the disclosure.

### Exemplary Embodiment 1

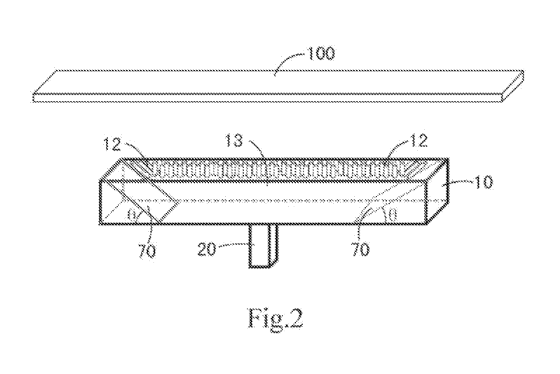

As shown in FIG. 2, the single point linear evaporation source system in the first embodiment of the disclosure is used to evaporate film on a substrate 100. The single point linear evaporation source system in the first embodiment comprises a body 10, a crucible 20, two guiding plates 70 and a plurality of nozzles 12.

The body 10 is parallel with the substrate 100 and disposed under the substrate 100, and is away from the substrate 100 for a certain distance. The body 10 is made of metal such as galvanized iron or titanium. The body 10 is elongated, and for example, is a cuboid formed by a top wall, a bottom wall, two side walls and two end walls. The body 10 is provided with an elongated chamber therein. To reduce the whole volume of the single point linear evaporation source system, the length of the body 10 can be less than that of the substrate 100, for example, the length of the body 10 can be ½˜⅘ of that of the substrate 100. A heater (not shown) for heating the body 10 may be provided to the body 10.

The crucible 20 is provided with an opening portion. The opening portion communicates with the center of the chamber. The crucible 20 is used to evaporate evaporation material disposed therein. A heater (not shown) for heating the crucible 20 may be disposed external to the crucible 20. The crucible 20 in the disclosure may also be replaced by other types of evaporators.

The two guiding plates 70 may be made of metal such as galvanized iron or titanium, and are inclinedly disposed at two ends of the chamber. The distance between two ends of the guiding plates 70 adjacent to the crucible 20 is smaller than the distance between two ends of the guiding plates 70 adjacent to the substrate 100. In the conventional single point linear evaporation source system, the cross section areas along different positions of the chamber are equal to each other, and the longitudinal section areas along different positions of the chamber are equal to each other too. As a result, the vapor concentration in the center of the chamber is larger than that at two ends of the chamber, and the evaporated film is not uniform. In the embodiment of the disclosure, the shape of the chamber of the body 10 is changed by disposing two guiding plates 70, such that the longitudinal horizontal section area of the chamber portion adjacent to the crucible 20 is smaller than that of the chamber portion adjacent to the substrate 100, and the cross section area in the center of the chamber is larger than the cross section area near the two ends of the chamber. That is, two ends of the chamber is tapered inwardly from the substrate 100 to the crucible 20.The space between the two ends of the chamber is reduced gradually, and the vapor concentration at two ends of the chamber increases. As a result, the vapor pressures in the center of the chamber and at two ends of the chamber are balanced, and the uniformity of the film deposited on the substrate 100 is improved.

Besides, when the center of the body 10 is aligned with the center of the substrate 100, the two guiding plates 70 are symmetrical about the central cross section 13 of the body 10. In this case, the longitudinal vertical section of the chamber is reversed-trapezoid-shaped. The periphery of the guiding plates 70 may be connected in a sealing manner with the body 10 to isolate vapor effectively. For example, sealing strips may be disposed between the periphery of the guiding plates 70 and the body 10. The guiding plates 70 and the body 10 may also be integrally formed. In the first embodiment, the guiding plate 70 is planar-shaped, and the guiding plates 70 may also be curved or have other shapes.

A plurality of nozzles 12 are disposed at a nozzle plate, and the nozzle plate may be integrally formed with the body 10, for example, the nozzle plate is the top wall of the body 10. The nozzles 12 are used to eject evaporating vapor towards the substrate 100. A plurality of nozzles 12 may be arranged in various manners. For example, the nozzles adjacent to the two ends of the body may be inclined. The nozzles 12 adjacent to the two ends of the body 10 may point to the end of the substrate. The nozzles 12 at the two end may be more concentrated than those at the center. The diameters of the nozzles 12 at the center of the body 10 may be smaller than those of the nozzles 12 at the two ends of the body 10, and for example, the diameters of the nozzles 12 increase gradually from the center of the body 10 to the two ends. The above arrangements of the nozzles 12 are beneficial to improve the uniformity of the film at the two ends of the substrate 100.

When the single point linear evaporation source system in the first embodiment is operated, the evaporation material in the crucible 20 is heated and vaporized, and is deposited at the lower surface of the substrate 100 via a plurality of nozzles 12 after flowing into the chamber.

### Exemplary Embodiment 2

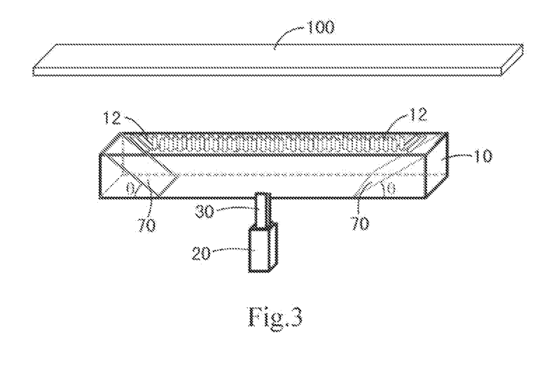

As shown in FIG. 3, the structure of the single point linear evaporation source system in the second embodiment is basically the same as that in the first embodiment. The only difference lies in that, the single point linear evaporation source system in the second embodiment further comprises a connection pipe 30. One end of the connection pipe 30 communicates with the opening portion of the crucible 20, while the other end communicates with the chamber. That is, the chamber communicates with the crucible 20 via the connection pipe 30. The inner diameter of the connection pipe is smaller than the size of the opening portion of the crucible 20, which may concentrate the vapor, reduce the vapor overflowing from the crucible and reduce material waste.

The structure at other parts of the single point linear evaporation source system in the second embodiment is the same as that in the first embodiment, and a detailed description thereof is omitted.

### Exemplary Embodiment 3

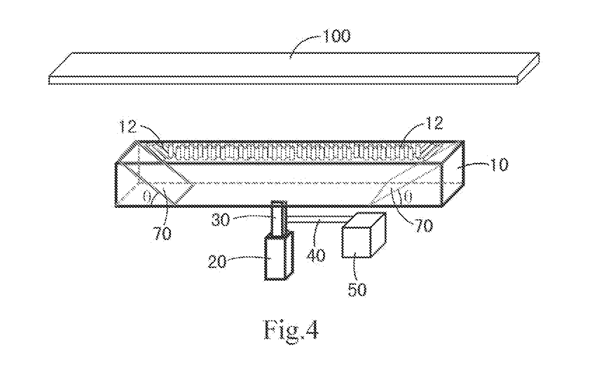

As shown in FIG. 4, the structure of the single point linear evaporation source system in the third embodiment is basically the same as that in the second embodiment, the only difference lies in that, the single point linear evaporation source system in the third embodiment further comprises an exhaust pipe 40, a vapor collecting box 50 and a valve. One end of the exhaust pipe 40 communicates with the connection pipe 30, and the other end communicates with the vapor collecting box 50. The valve (not shown) is assembled inside the connection pipe 30.

When the single point linear evaporation source system is operated, the valve permits connection of the crucible 20 to the chamber and disconnection between the crucible 20 and the exhaust pipe 40, which allows the vapor out of the crucible 20 flows to the chamber. When the single point linear evaporation source system is stopped, the valve permits disconnection between the crucible 20 and the chamber and connection of the chamber to the exhaust pipe 40, which allows the vapor left in the chamber is recycled to the vapor collecting box 50 via the exhaust pipe 40, thereby reduce material waste.

The structure at other parts of the single point linear evaporation source system in the third embodiment is the same as that in the second embodiment, and a detailed description thereof is omitted.

### Exemplary Embodiment 4

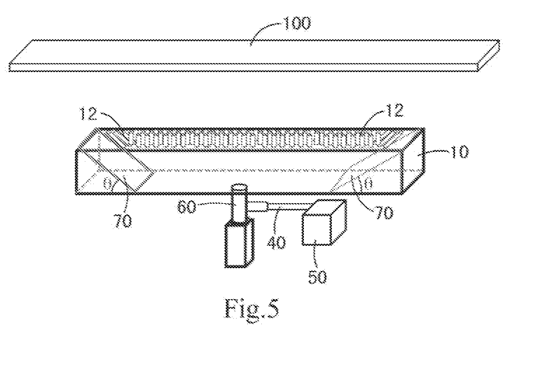

As shown in FIG. 5, the structure of the single point linear evaporation source system in the fourth embodiment is basically the same as that in the first embodiment, the only difference lies in that, the single point linear evaporation source system in the fourth embodiment further comprises a three-way valve 60, an exhaust pipe 40 and a vapor collecting box 50. The three-way valve 60 is provided with three ports, in which a first port communicates with the crucible 20, a second port communicates with the chamber of the body 10, and a third port communicates with one end of the exhaust pipe 40. The other end of the exhaust pipe 40 communicates with the vapor collecting box 50. In the fourth embodiment, the crucible 20, the chamber and the exhaust pipe 40 may communicate with each other via the three-way valve 60.

When the single point linear evaporation source system is operated, the first port and the second port of the three-way valve 60 are open, and the third port is closed. The vapor from the crucible flows to the chamber. When the single point linear evaporation source system is stopped, the first port of the three-way valve is closed, and the second port and the third port are open, which allows the vapor left in the chamber to be recycled in the vapor collecting box 50, thereby reducing material waste.

The structure at other parts of the single point linear evaporation source system in the fourth embodiment is the same as that in the first embodiment, and a detailed description thereof is omitted.

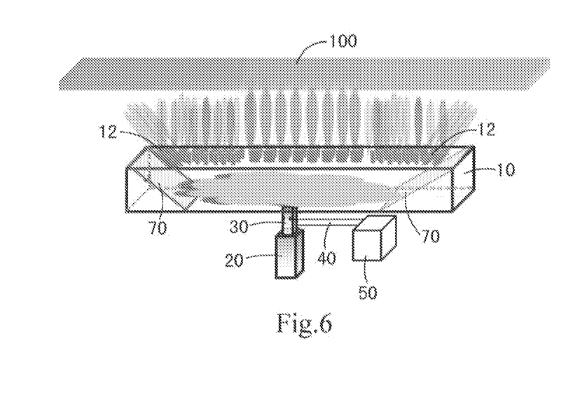

As show in FIG. 6, FIG. 6 is a perspective view diagram showing the effect of the single point linear evaporation source system in the third and fourth embodiment. As shown in FIG. 6, the vapor pressure in the chamber is balanced. In addition, with the inclined nozzles 12 at two sides, the vapor concentration and pressure ejected from the nozzle 12 are balanced. As a result, the thickness of the film deposited on the substrate 100 is uniform, and the film uniformity is tested to be smaller than ±3%. After the single point linear evaporation source system in the embodiment of the disclosure is finished operating, vapor in the chamber can be recycled into the vapor collecting box 50, and the material utilization is larger than 30%.

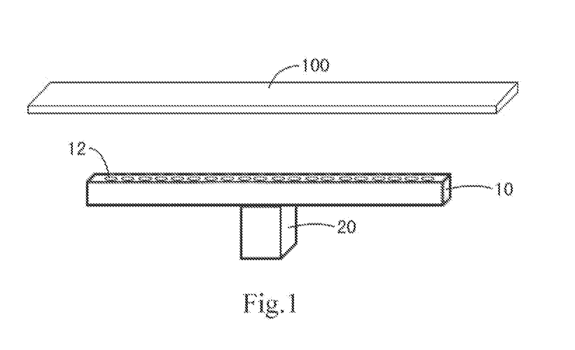

In the single point linear evaporation source system in the embodiment of the disclosure, the inclined angle θ of the guiding plates 70 relative to the bottom of body 10 is related to the length difference between the substrate 100 and the body 10. The larger the length difference is, the smaller the inclined angle θ is. Therefore, the inclined angle θ between the guiding plates 70 and the body 10 varies according to the length difference between the substrate 100 and the body 10. In addition, the inclined angles of the two guiding plates 70 relative to the body 10 can be the same (as shown in FIG. 1 to FIG. 5), or different (not shown in the Figs).

### Exemplary Embodiment 5

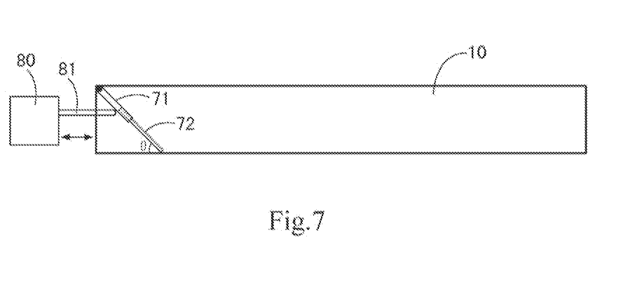

As shown in FIG. 7, in the single point linear evaporation source system according to the fifth embodiment of the disclosure, the guiding plates 70 are assembled to the body 10 with the inclined angle θ adjustable. For example, the single point linear evaporation source system in the fifth embodiment further comprises an electric engine or a motor 80. Each guiding plate 7 comprises a first plate 71 and a second plate 72. A top portion of the first plate 71 is connected to a top end of the end portion of the body 10 in a known method. The first plate 71 is provided with a hollow space at a lower portion, and an upper portion of the second plate 72 may be inserted in the lower portion of the first plate 71, and the first plate 71 and the second plate 72 therefore can be slidably connected to each other. In the fifth embodiment, it is also possible that a hollow space be provided at the upper portion of the second plate 72, and the lower portion of the first plate 71 may be inserted in the hollow space of the second plate 72.

When it is needed to adjust the inclined angle θ, an output shaft 81 passes through a through hole at an end wall of the body 10 and abuts against the first plate 71. When the output shaft 81 extends outwardly, the output shaft 81 pushes the first plate 71, such that the second plate 72 slides downwardly, and moves away from the electric engine 80 while keeping contact with the bottom wall of the body 10. When the output shaft 81 is retracted inwardly, the output shaft 81 pulls the first plate 71 to rotate around its top end portion, and a bottom end portion of the second plate 72 slides towards the electric engine 80 along the bottom wall of the body 10 while keeping contact with the bottom wall of the body 10.

In the single point linear evaporation source system in the fifth embodiment of the disclosure, the inclined angle θ between the guiding plates 70 and the body 10 can be adjusted, as a result, the single point linear evaporation source system can satisfy different vapor pressure requirements.

### Exemplary Embodiment 6

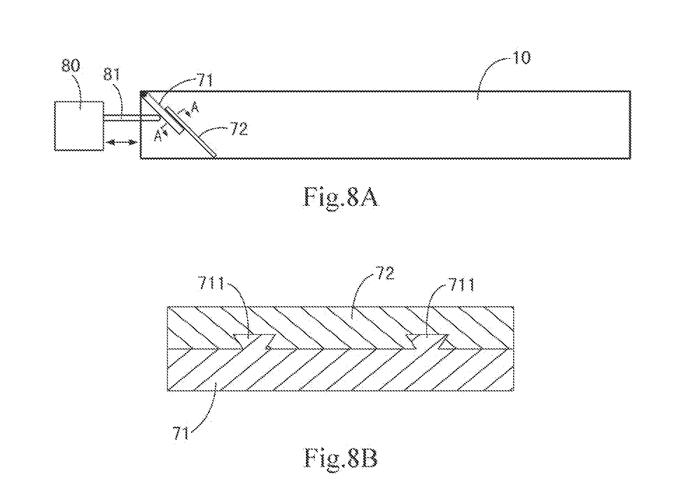

As shown in FIG. 8A and FIG. 8B, the structure of the single point linear evaporation source system in the sixth embodiment is basically the same as that in the fifth embodiment, the only difference lies in that, the upper portion of the second plate 72 overlaps the bottom portion of the first plate 71. The second plate 72 is provided with two dovetail slots, and the first plate 71 is provided with two dovetail protruding bars 711 whose shapes match with the dovetail slots respectively. The second plate 72 and the first plate 71 are slidably connected with each other through the engagement of the dovetail protruding bars 711 with dovetail slots. In the sixth embodiment, it is also possible to provide the dovetail slots at the first plate 71 and provide the dovetail protruding bars 711 at the second plate 72. The number of the dovetail slots is not limited to two, rather, it may also be one, three or four, etc.

The structure at other parts of the single point linear evaporation source system in the sixth embodiment is the same as that in the fifth embodiment, and a detailed description thereof is omitted.

### Exemplary Embodiment 7

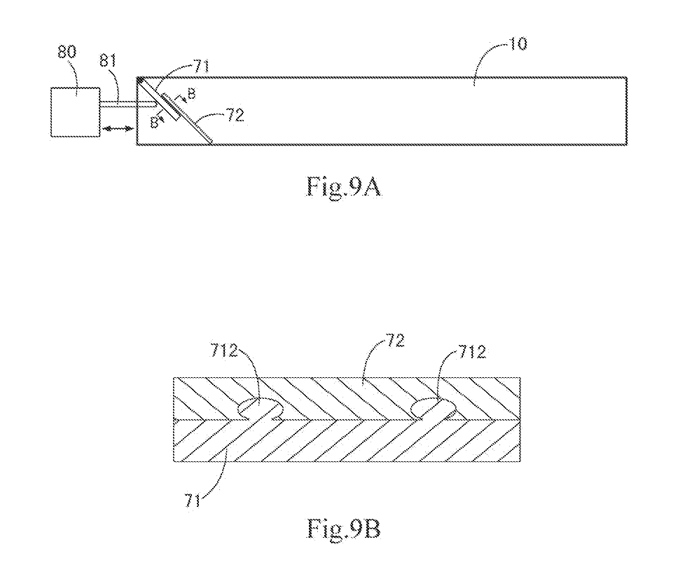

As shown in FIG. 9A and FIG. 9B, the structure of the single point linear evaporation source system in the seventh embodiment is basically the same as that in the fifth embodiment. The only different lies in that, the upper portion of the second plate 71 overlaps the lower portion of the first plate 71. The second plate 72 is provided with two ellipse slots, and the first plate 71 is provided with two ellipse protruding bars 712 whose shapes match the two ellipse slots respectively. The second plate 72 and the first plate 71 are slidably connected with each other through the engagement of the ellipse protruding bars with the ellipse protruding slots. In the seventh embodiment, it is also possible to provide the ellipse slots at the first plate and provide the ellipse protruding bars 712 at the second plate 72. The number of the ellipse slots is not limited to two, rather, it may also be one, three or four, etc.

A skilled person in the art should know that, the method for achieving slidable connection between the second plate 72 and the first plate 71 is not limited to be the matched ellipse recesses and ellipse protruding bars, or the matched dovetail recesses and dovetail protruding bars. The slidable connection may also be achieved by recesses and protruding bars with other shapes, or other connecting methods, as long as the slidable connection can be achieved.

Based on the above technical solution, the beneficial effects of the single point linear evaporation source system lie in that, in the single point linear evaporation source system of the disclosure, by disposing two inclined guiding plates inside the chamber of the body, the shape of the chamber is changed, the longitudinal section of the chamber at the position adjacent to the evaporator is relatively small, and that adjacent to the substrate is relatively large, thereby improving the balance of the vapor pressure inside the chamber, making the vapor pressures at the center position and two ends of the chamber unanimous, and improving the uniformity of the film deposited on the substrate.

Further scope of applicability of the present disclosure will become apparent from the detailed description given above. However, it should be understood that the detailed description and specific examples, while indicating exemplary embodiments of the disclosure, are given by way of illustration only, since various changes and modifications within the spirit and scope of the disclosure will become apparent to those skilled in the art from the above detailed description.

And it should be noted that the above embodiments is only illustrated for describing the technical solution of the disclosure and not restrictive, and although the disclosure is described in detail by referring to the aforesaid embodiments, the skilled in the art should understand that the aforesaid embodiments can be modified and portions of the technical features therein may be equally changed, which does not depart from the spirit and scope of the technical solution of the embodiments of the disclosure.

What is claimed is:

1. A single point linear evaporation source system for depositing film on a substrate comprising:
a body with elongated shape comprising an elongated chamber, the surface of the body towards the substrate being provided with a plurality of nozzles communicating with the chamber, the nozzles being used for ejecting evaporating vapor towards the substrate;
an evaporator with an opening portion communicating with the chamber, the evaporator being used for evaporating evaporation material disposed therein;
two guiding plates disposed inclinedly at two ends of the chamber, the periphery of the guiding plates being in sealing connection with the body, and the distance between two ends of the two guiding plates adjacent to the substrate being larger than the distance between two ends of the two guiding plates adjacent to the evaporator.

2. The single point linear evaporation source system according to claim 1, wherein the guiding plates are disposed at the body with an angle between the guiding plates and the body adjustable.

3. The single point linear evaporation source system according to claim 2, wherein the single point linear evaporation source system further comprises an electric engine or a motor, each of the guiding plates comprises a first plate and a second plate, a top portion of the first plate is rotatably connected to the body, the upper portion of the second plate is slidably connected to the lower portion of the first plate, an output shaft of the electric engine or the motor passes through a through hole of the body and is connected to the first plate.

4. The single point linear evaporation source system according to claim 3, wherein one of the lower portion of the first plate and the upper portion of the second plate is provided with a hollow space, and the other one of the lower portion of the first plate and the upper portion of the second plate is capable of inserting in the hollow space.

5. The single point linear evaporation source system according to claim 3, wherein the upper portion of the second plate overlaps the lower portion of the first plate, one of the second plate and the first plate is provided with at least a recess, the other one of the second plate and the first plate is provided with at least a protruding bar whose shape matches the recess.

6. The single point linear evaporation source system according to claim 5, wherein the recess is dovetail-shaped or ellipse-shaped.

7. The single point linear evaporation source system according to claim 1, wherein the single point linear evaporation source system further comprising:
a connection pipe whose one end communicates with the opening portion of the evaporator, and the other end communicates with the chamber, an inner diameter of the connection pipe is smaller than that of the opening portion of the evaporator.

8. The single point linear evaporation source system according to claim 7, wherein the single point linear evaporation source system further comprises:
an exhaust pipe whose one end communicates with the connection pipe;
a vapor collecting box communicating with the other end of the exhaust pipe;
a valve assembled inside the connection pipe;
when the single point linear evaporation source system is operated, the valve is in the state of connecting the evaporator and the chamber and cutting off the evaporator and the exhaust pipe, when the single point linear evaporation source system is stopped, the valve is in the state of cutting off the evaporator and the chamber and connecting the chamber and the exhaust pipe.

9. The single point linear evaporation source system according to claim 1, wherein the single point linear evaporation source system further comprises:
a three-way valve comprising three ways, in which a first way communicates with the evaporator, a second way communicates with the chamber of the body;
an exhaust pipe whose one end communicates with a third way of the three-way valve;
a vapor collecting box connected to the other end of the exhaust pipe;
when the single point linear evaporation source system is operated, the first way, the second way are opened, and the third way is closed, when the single point linear evaporation source system is stopped, the first way is closed, and the second way and the third way are opened.

10. The single point linear evaporation source system according to claim 1, wherein the nozzles adjacent to the two ends of the body point to the end of the substrate.

11. The single point linear evaporation source system according to claim 1, wherein the diameters of the nozzles in the center of the body are smaller than those at two ends of the body.

12. The single point linear evaporation source system according to claim 1, wherein the length of the body is smaller than the length of the substrate.

13. The single point linear evaporation source system according to claim 12, wherein the length of the body is ½˜⅘ of the length of the substrate.

14. The single point linear evaporation source system according to claim 1, wherein the two guiding plates are symmetrical to each other.

15. The single point linear evaporation source system according to claim 1, wherein the nozzles adjacent to the two ends of the body are disposed inclinedly.

16. The single point linear evaporation source system according to claim 1, wherein the nozzles are disposed at a nozzle plate, and the nozzle plate is disposed on the body.

17. The single point linear evaporation source system according to claim 16, wherein the nozzle plate and the body are integrally formed.

18. The single point linear evaporation source system according to claim 1, wherein the guiding plates and the body are integrally formed.

19. The single point linear evaporation source system according to claim 1, wherein the body and the guiding plates are made of galvanized iron or titanium.

20. The single point linear evaporation source system according to claim 1, wherein the guiding plates are curved.
